(19) United States
(12) Patent Application Publication
(10) Pub. No.: US 2025/0176305 A1
(43) Pub. Date: May 29, 2025

(54) BIFACIAL THIN FILM SOLAR CELL AND METHOD FOR FABRICATING THE SAME

(71) Applicant: KOREA INSTITUTE OF SCIENCE AND TECHNOLOGY, Seoul (KR)

(72) Inventors: Jeung-hyun JEONG, Seoul (KR); Won Mok KIM, Seoul (KR); Gee Young KIM, Seoul (KR); Jae-Young KIM, Seoul (KR); Eun Pyung CHOI, Seoul (KR); Kyeong Seok LEE, Seoul (KR)

(73) Assignee: KOREA INSTITUTE OF SCIENCE AND TECHNOLOGY, Seoul (KR)

(21) Appl. No.: 18/642,165

(22) Filed: Apr. 22, 2024

(30) Foreign Application Priority Data
Nov. 23, 2023 (KR) 10-2023-0164397

(51) Int. Cl. H01L 31/0224; H01L 31/0216; H01L 31/18

(52) U.S. Cl. CPC H10F 77/215; H10F 71/138; H10F 77/244; H10F 77/315

(57) ABSTRACT

The present invention relates to a bifacial thin-film solar cell capable of enhancing photovoltaic performance on the rear side by reducing interfacial resistance and recombination characteristics at the interface between the rear transparent electrode and the CIGS in implementing a CIGS-based bifacial thin-film solar cell, and a manufacturing method thereof. The bifacial thin film solar cell according to the present invention is characterized by including: a rear transparent electrode stacked on a transparent substrate; a rear passivation layer stacked on the rear transparent electrode; a conductive thin film pattern formed in some regions on the rear passivation layer; a light-absorbing layer stacked on the front surface of the rear passivation layer including the conductive thin film pattern; a buffer layer stacked on the light-absorbing layer; and a front transparent electrode stacked on the buffer layer.

### DESCRIPTION OF GOVERNMENT-SPONSORED RESEARCH

This study was conducted with the support of the Ministry of Science and ICT and the National Research Foundation of Korea [Research project name: Climate change response technology development; Research task name: Development of High-Efficiency Transparent CIGS Photovoltaic Module; Task identification number: 1055001324; Task number: 2019M1A2A2072412].

### CROSS REFERENCE TO RELATED APPLICATIONS

This application claims the benefit under 35 USC 119(a) of Korean Patent Application No. 10-2023-0164397 filed on Nov. 23, 2023, in the Korean Intellectual Property Office, the entire disclosure of which is incorporated herein by reference for all purposes.

### BACKGROUND OF THE INVENTION

### Field of the Invention

The present invention relates to a bifacial thin-film solar cell and a method of manufacturing the same. More specifically, the present invention relates to a bifacial thin-film solar cell capable of enhancing photovoltaic performance on the rear side by reducing interfacial resistance and recombination characteristics at the interface between the rear transparent electrode and the CIGS in implementing a CIGS-based bifacial thin-film solar cell, and a manufacturing method thereof.

### Description of the Related Art

CIGS (Cu(In₁₋ₓGaₓ)(Se,S)₂) thin film solar cells are in the spotlight as high-efficiency thin film solar cells with high photovoltaic efficiency of up to 23.6% and excellent stability. In addition, the CIGS thin film solar cells have a band gap that can be changed in the range of 1.0-1.7 eV compared to silicon solar cells with a fixed band gap of 1.1 eV, making them easy to apply according to usage requirements. Moreover, they have excellent electro-optical characteristics and can be applied to various fields such as buildings, automobiles, and military use due to their flexibility and light weight.

Meanwhile, a bifacial solar cell capable of generating photovoltaic power not only on the front surface but also on the rear surface of the solar cell is a technology that can improve photovoltaic power generation performance of the solar cell. Even in the case of the CIGS thin film solar cell, a bifacial type can be implemented by replacing the rear electrode made of Mo with a transparent conductive oxide (TCO). For example, a bifacial solar cell in the form of sequentially stacking a rear TCO, a light-absorbing layer (CIGS), a buffer layer, and a front TCO on a glass substrate can be implemented.

However, the bifacial solar cell incorporating this configuration demonstrates poor carrier transport properties at the TCO/CIGS interface, attributable to either work function mismatch between TCO and CIGS or elevated interfacial resistance resulting from GaOₓ reaction layer at the interface. Concurrently, it is characterized by an increased recombination rate of electron-hole (e-h) pairs at the interface, which, in conjunction, impairs the photovoltaic performance on the rear side. Therefore, it is necessary to reduce the rear interfacial resistance and suppress rear recombination characteristics.

First, in order to improve the rear interfacial transport properties, a method of applying a thin Mo thin film layer between the rear TCO and the CIGS or lowering the process temperature of the CIGS photoactive layer to 400° C. or less to suppress the formation of GaOₓ has been proposed. Those methods were highly effective in lowering the rear interfacial resistance. However, there is no evidence that the above methods of lowering the interfacial resistance are effective in suppressing the rear recombination.

As a method for improving the rear recombination characteristics, there has been proposed a method of forming a CIGS light-absorbing layer to have a composition distribution that increases a Ga/(Ga+In) ratio toward the TCO/CIGS interface so that a bandgap gradient occurs in the rear TCO direction. This approach was found to enhance the photocurrent generated by rear-side light incidence, operating on a principle that diminishes electron-hole (e-h) recombination. It does so by propelling photoexcited electrons away from the TCO/CIGS rear interface, facilitated by a gradient in the bandgap. This strategic displacement reduces e-h recombination near the interface. However, it's important to note that this method does not directly passivate the interface. Consequently, while it mitigates interface recombination to a degree, it does not eliminate it entirely, highlighting a fundamental limitation in fully suppressing interfacial recombination through this approach alone. (Efficiency boost of bifacial Cu(In,Ga)Se₂ thin-film solar cells for flexible and tandem applications with silver-assisted low-temperature process (see Nature Energy, v. 8, p. 40-51, 2023)).

As another method, there has been proposed a technology in which Ga₂O₃ formed at the interface between the rear TCO and CIGS serves as a passivation layer, and conductive metal nanoparticles are dispersed within the Ga₂O₃, whereby a passivation by the Ga₂O₃ and an interfacial resistance reduction by metal nanoparticles dispersed in the Ga₂O₃ can be expected (Korean Patent No. 2009308). However, the Ga₂O₃, which is formed as a by-product in the growth process of the CIGS light-absorbing layer, acts as a source of high interfacial resistance and defects, as previously discussed, so the passivation effect by Ga₂O₃ is bound to be limited.

Meanwhile, as a structure for improving rear passivation characteristics and electrical characteristics, although not related to the bifacial solar cell, US Patent Publication No. 2018-0138347 discloses a structure in which a light reflective metal layer 104, an Al₂O₃ passivation layer 106, a light-absorbing layer 102, a buffer layer 802, and a transparent electrode 804 are sequentially stacked on a substrate, and a plurality of openings penetrating the Al₂O₃ passivation layer 106 is provided with an electrical contact 108. It describes that through this structure, the rear passivation characteristics by the Al₂O₃ passivation layer and the electrical characteristics by the electrical contact 108 that induces ohmic contact between the light-absorbing layer 102 and the light reflective metal layer 104 can be expected to be improved. The technology disclosed in US 2018-0138347 shares some technical goals with the present invention in terms of improving the rear passivation characteristics and electrical characteristics, but there are clear differences in whether it is a bifacial type, constituent materials of the rear passivation layer, and the coupling structure of the rear passivation layer and the conductive thin film pattern, which will be described later in the description of the present invention.

### SUMMARY OF THE INVENTION

### Technical Problem

The present invention has been devised to solve the above problems, and its object is to provide a bifacial thin-film solar cell capable of enhancing photovoltaic performance on the rear side by reducing interfacial resistance and recombination characteristics at the interface between the rear transparent electrode and the CIGS in implementing a CIGS-based bifacial thin-film solar cell, and a manufacturing method thereof.

### Technical Solution

A bifacial thin film solar cell according to the present invention for achieving the above object is characterized by including: a rear transparent electrode stacked on a transparent substrate; a rear passivation layer stacked on the rear transparent electrode; a conductive thin film pattern formed in some regions on the rear passivation layer; a light-absorbing layer stacked on the front surface of the rear passivation layer including the conductive thin film pattern; a buffer layer stacked on the light-absorbing layer; and a front transparent electrode stacked on the buffer layer.

The rear passivation layer may be formed of TiOₓ or TaOₓ.

The electrical resistivity of TiOₓ may be greater than 1 Ωcm.

The rear passivation layer may be formed of TiOₓ or TaOₓ doped with any one element among Nb, Sb, and S.

The electrical resistivity of TiOₓ doped with any one of Nb, Sb, and S may be greater than 1 Ωcm.

The conductive thin film pattern may have a dot shape or a linear shape, and a plurality of conductive thin film patterns may be arranged on the rear passivation layer to be spaced apart from each other.

The total area of the plurality of conductive thin film patterns may not exceed 20% of the area of the rear passivation layer.

When the conductive thin film pattern has a dot shape, the conductive thin film pattern may have a length or diameter of 0.1 to 2 μm, a thickness of 0.1 to 2 nm, and a distance between the conductive thin film patterns which is equal to or less than a carrier diffusion length (L_{D}) in the light-absorbing layer.

When the conductive thin film pattern has a linear shape, the linear conductive thin film pattern may have a width of 0.1 to 2 μm, a thickness of 0.1 to 2 nm, and a distance between the conductive thin film patterns which is equal to or less than a carrier diffusion length (L_{D}) in the light-absorbing layer.

The conductive thin film pattern may be formed of molybdenum (Mo).

The stacked thickness of the rear passivation layer may be 2 to 4 nm.

The light-absorbing layer may be formed of CIGS (Cu(In₁₋ₓ, Gaₓ)(Se,S)₂).

The rear transparent electrode and the front transparent electrode may be formed of any one of indium-based oxide, zinc-based oxide, and tin-based oxide, wherein the indium-based oxide may be any one of InOₓ, ITO, (W, Ce, Mo)-doped InOₓ, and IZO, the zinc-based oxide may be (Al, Ga, B, Ti, F, H)-doped ZnOₓ, and the tin-based oxide may be (F, Sb)-doped SnOₓ.

The buffer layer may be provided between the light-absorbing layer and the front transparent electrode, and the buffer layer may be formed of any one of CdS, InS(O,OH), ZnS(O, OH), ZnMgO, ZnTiO, ZnSnO, or a combination thereof.

The front transparent electrode, light-absorbing layer, and rear passivation layer in a specific region may be removed to provide a light-transmitting portion region in which the rear transparent electrode is exposed.

A P1 region may be provided in which the rear passivation layer and the rear transparent electrode are removed in a certain area, a P2 region may be provided in which the buffer layer and the light-absorbing layer are removed in a certain area, and a P3 region may be provided in which the front transparent electrode, the buffer layer, and the light-absorbing layer are removed in a certain area, wherein the rear transparent electrodes of neighboring cells may be insulated by the P1 region, the rear transparent electrode and the front transparent electrode of neighboring cells may be connected by the P2 region, and the front transparent electrodes of neighboring cells may be insulated by the P3 region.

A method of manufacturing a bifacial thin film solar cell according to the present invention is characterized by including the steps of: forming a rear transparent electrode on a transparent substrate; sequentially stacking a rear passivation layer on the rear transparent electrode; forming a conductive thin film pattern on the rear passivation layer; forming a light-absorbing layer on the front surface of the rear passivation layer including the conductive thin film pattern; and forming a front transparent electrode on the light-absorbing layer.

The step of forming a conductive thin film pattern on the rear passivation layer may include the substeps of: forming a mask that exposes some regions of the rear passivation layer on the rear passivation layer, depositing a conductive metal on the front surface of the rear passivation layer including the mask, and removing the mask to form a conductive thin film pattern in some regions of the rear passivation layer.

The method may further include a step of removing the front transparent electrode and the light-absorbing layer in a specific region to form a light-transmitting portion region in which the rear transparent electrode is exposed.

The method may further include a step of scribing the rear transparent electrode and the rear passivation layer in a certain area along the P1 region to divide them into a plurality of cells and insulating the rear transparent electrode between neighboring cells in a state in which the conductive thin film pattern is formed on the rear passivation layer before forming the light-absorbing layer.

The method may further include a step of exposing the rear passivation layer by scribing the light-absorbing layer along the P2 region after forming the light-absorbing layer.

The method may further include a step of insulating the front transparent electrode between neighboring cells by scribing the front transparent electrode and the light-absorbing layer along the P3 region in a state in which the front transparent electrode is stacked.

### Advantageous Effects

The bifacial thin-film solar cell according to the present invention has the following effects:

Through the combined structure of the rear passivation layer and the conductive thin film pattern, the rear passivation characteristics and rear interfacial transport characteristics can be improved, thereby enhancing the photocurrent characteristics by light incident from the rear of the bifacial thin film solar cell.

### BRIEF DESCRIPTION OF THE DRAWINGS

FIG. 1 is a schematic diagram of a bifacial thin film solar cell according to an embodiment of the present invention.

FIGS. 2 and 3 are reference diagrams showing the form of a conductive thin film pattern according to an embodiment of the present invention.

FIGS. 4A to 4D are cross-sectional views illustrating the processes of a method of manufacturing a bifacial thin film solar cell according to an embodiment of the present invention.

FIGS. 5 and 6 are reference diagrams showing a cross-sectional view of regions P1 to P3 and a top view of a light-transmitting portion region (T) of a bifacial thin film solar cell according to an embodiment of the present invention, respectively.

FIGS. 7A and 7B are experimental results showing each current-voltage characteristic upon front and rear light incident according to Experimental Example 1.

FIGS. 8A and 8B are experimental results showing each current-voltage characteristic upon front and rear light incident according to Experimental Example 2.

FIGS. 9A and 9B show TEM-EDS analysis results of ITO/TiO₂ (4 nm)/CIGS prepared according to Experimental Example 1.

FIGS. 10A and 10B show TEM-EDS analysis results of ITO/TiO₂ (4 nm)/Mo(0.5 nm)/CIGS prepared according to Experimental Example 2.

FIG. 11 is an experimental result showing electrical resistivity characteristics of Nb-doped TiO₂ (TNO) according to oxygen content in a sputtering gas.

FIGS. 12A and 12B are experimental results showing front photocurrent characteristics and rear photocurrent characteristics of a thin film solar cell to which TNO with an oxygen content of 0.08% and 0.2% in the sputtering Ar process gas is applied.

FIGS. 13A and 13B are experimental results showing front photocurrent characteristics and rear photocurrent characteristics of a thin film solar cell to which TNO and Mo thin film layers (0.5 nm) with an oxygen content of 0.08% and 0.2% in the sputtering Ar process gas were applied.

### DETAILED DESCRIPTION OF THE INVENTION

In implementing a bifacial thin film solar cell, the present invention proposes a technology capable of maximizing the photovoltaic performance on the rear side of a bifacial thin-film solar cell by passivating defects present at the interface between a rear transparent electrode and a light-absorbing layer to minimize carrier recombination at the interface, while improving an ohmic contact characteristics between the rear transparent electrode and the light-absorbing layer to facilitate a movement of holes (+) generated in the light-absorbing layer to the rear transparent electrode.

To implement this, the present invention presents a structure in which a rear passivation layer formed of TiOₓ or TaOₓ, an n-type metal oxide, is provided between the rear transparent electrode and the light-absorbing layer, and a conductive thin film pattern is provided on the rear passivation layer.

The rear passivation layer formed of TiOₓ (or TaOₓ) is provided between the rear transparent electrode and the light-absorbing layer to passivate defects present in the rear of the light-absorbing layer, thereby preventing electrons (−) generated in the light-absorbing layer from recombining with the defects and disappearing.

The conductive thin film pattern is provided on some regions of the rear passivation layer and inserted into the light-absorbing layer, minimizing interfacial resistance between the rear passivation layer formed of TiOₓ (or TaOₓ) and CIGS and inducing ohmic contact between the light-absorbing layer and the rear transparent electrode.

That is, under the stacked structure of the rear passivation and the conductive thin film pattern, the rear passivation layer in an region where the conductive thin film pattern is not provided serves to passivate the defects present in the rear of the light-absorbing layer, and the conductive thin film pattern provided on some regions of the rear passivation layer serves to lower the interfacial resistance between the light-absorbing layer and the rear passivation layer to induce ohmic contact between the light-absorbing layer and the rear transparent electrode.

In general, a passivation layer made of SiO₂ or SiNₓ has been applied to passivate a p+ region (p-type substrate or p-type emitter) in crystalline silicon solar cells, and recently, it has been proven that Al₂O₃ is highly effective in passivating a p-type emitter of a n-type substrate. Al₂O₃ stacked on a silicon substrate has a large amount of negative fixed charges by heat treatment. These charges are mainly located at the interface between the Al₂O₃ thin film and the crystalline silicon substrate and forms a very strong negative electric field in the p+ region of the silicon surface, thereby pushing photo-excited electrons from the interface to show low recombination properties.

As such, Al₂O₃ is a highly effective material as a passivation layer for the p+ region of a crystalline silicon solar cell. Therefore, it may be considered naturally to apply Al₂O₃ as a passivation layer of a CIGS-based thin film solar cell. However, when Al₂O₃ is applied as a passivation layer in a crystalline silicon solar cell, a structure in which the electrode penetrates Al₂O₃ is required for ohmic contact between the electrode and the p+ region because Al₂O₃ is a non-conductor. Accordingly, if Al₂O₃ is applied as a passivation layer to a CIGS-based thin film solar cell, the penetration of Al₂O₃ is inevitably required for ohmic contact between the electrode and the light-absorbing layer. For this reason, it is difficult to apply Al₂O₃ as a passivation layer in a CIGS-based thin film solar cell. For reference, US 2018-0138347 proposes a structure in which an Al₂O₃ passivation layer 106 is provided without a penetration portion between a light reflection metal layer 10 and a light-absorbing layer 102, but the light reflection metal layer 10 is not an electrode where carriers are collected.

In the present invention, TiOₓ(or TaOₓ) is applied as the rear passivation layer of the CIGS-based thin film solar cell as described above. As is known, since TiOₓ and TaOₓ are n-type materials, it is theoretically unsuitable to apply an n-type material such as TiO₂ for passivation of CIGS, a p-type semiconductor. This is because when the n-type material is applied as the passivation layer for passivation of the CIGS interface, the transfer of holes (+) is blocked by the n-type passivation layer independently of its passivation capability.

Despite this inadequacy in principle, the combined structure of the rear passivation formed of TiOₓ (or TaOₓ) and the conductive thin film pattern can resolve the barrier at the TiOₓ/CIGS interface that causes carrier blocking. In addition, since TiOₓ is not an insulator unlike Al₂O₃ which is a nonconductor, ohmic contact between the rear transparent electrode and the light-absorbing layer can be induced without penetration of TiOₓ. That is, the rear passivation characteristic is achieved by TiOₓ provided between the rear transparent electrode and the light-absorbing layer; the interfacial resistance between TiOₓ and CIGS is resolved by the conductive thin film pattern; and ohmic contact between the rear transparent electrode and the light-absorbing layer can be induced without penetration of TiOₓ by taking advantage of the fact that TiOₓ is conductive and that the conductivity of TiOₓ can be adjusted by changing the oxygen content (and/or impurity content) in the sputtering gas.

Hereinafter, a bifacial thin film solar cell according to an embodiment of the present invention will be described in detail with reference to the drawings.

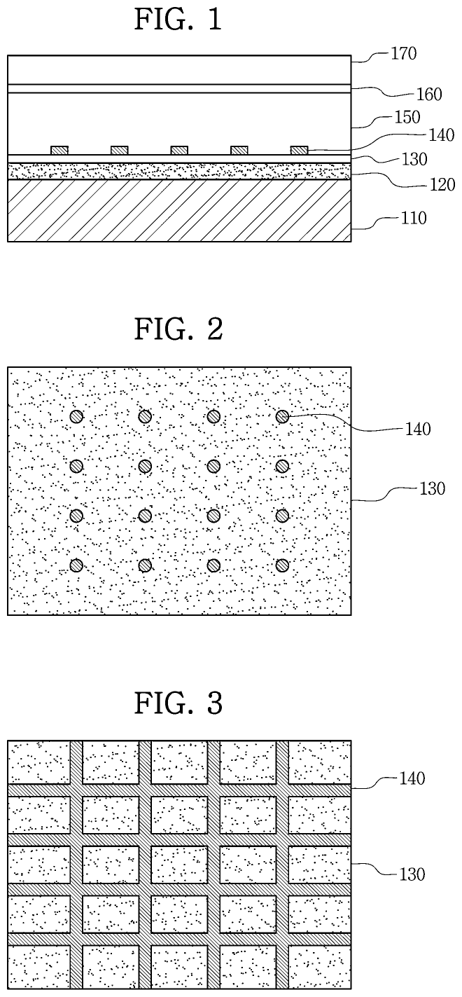

Referring to FIG. 1, a bifacial thin film solar cell according to an embodiment of the present invention has a structure in which a rear transparent electrode 120, a rear passivation layer 130, a light-absorbing layer 150, a buffer layer 160, and a front transparent electrode 170 are sequentially stacked on a transparent substrate 110, and a conductive thin film pattern 140 is provided on the rear passivation layer 130.

The light-absorbing layer 150 absorbs light to generate electron (−) and hole (+) pairs through photoelectric conversion, wherein the electron (−) generated in the light-absorbing layer 150 is moved to the front transparent electrode 170, and the hole (+) is moved to the rear transparent electrode 120. Here, the light-absorbing layer 150 and the front transparent electrode 170 form a p-n junction. Additionally, the light-absorbing layer 150 is formed of CIGS (Cu(In₁₋ₓ, Gaₓ)(Se,S)₂).

The rear passivation layer 130 is provided between the rear transparent electrode 120 and the light-absorbing layer 150 to serve to passivate defects existing on the rear surface of the light-absorbing layer 150, thereby minimizing the disappearance of the photoexcited electrons (−) formed in the region of the light-absorbing layer 150 in contact with the rear transparent electrode 120 from the light-absorbing layer 150 by recombining with the defects.

The rear passivation layer 130 is formed of TiOₓ or TaOₓ, which is an n-type metal oxide. Additionally, TiOₓ or TaOₓ doped with any one element of Nb, Sb, and S may also be applied as the rear passivation layer 130. Most preferably, TiOₓ or Nb-doped TiOₓ (TNO, titanium niobium oxide) may be applied as the rear passivation layer 130. Hereinafter, for convenience of description, the description will be based on TiOₓ.

Although the light-absorbing layer 150 formed of CIGS is a p-type semiconductor, TiOₓ, an n-type metal oxide, is applied as the passivation layer of the light-absorbing layer 150 because this material has excellent passivation characteristics and can control its conductivity.

Al₂O₃ was previously mentioned as a representative passivation material for crystalline silicon solar cells in the ‘Background Art’. The Al₂O₃ has excellent passivation characteristics, but due to its electrical nonconductivity, the electrode must penetrate Al₂O₃, which is a passivation layer, in order for the electrode (e.g., the front electrode) to make ohmic contact with the p-type semiconductor layer.

Al₂O₃ has an energy band gap of about 7.0 to 7.6 eV and thus is a nonconductor, while TiOₓ, an n-type metal oxide, has an energy band gap of about 3.2 eV and thus is conductive.

As such, since TiOₓ, an n-type metal oxide, is conductive unlike Al₂O₃, which is a non-conductor, the penetration of the electrode into the passivation layer is not required when applied to the passivation layer. In addition, with regard to the passivation characteristics of TiOₓ, referring to the experimental example described later, it can be seen that when TiOₓ is applied to the rear passivation layer 130 at a thickness of 2 to 4 nm, the rear photoelectric conversion efficiency increases by two times or more compared to the case where TiOₓ is not applied, and these results disprove that the rear passivation characteristics are improved by TiOₓ.

As a requirement for improving photoelectric conversion efficiency of CIGS-based bifacial thin-film solar cells, the most important thing is to improve the rear recombination characteristics and rear interface transport characteristics, which can be achieved by applying TiOₓ as the rear passivation layer 130 and providing a conductive thin-film pattern 140 on the rear passivation layer 130.

As described above, it is confirmed through the experimental examples that the rear passivation characteristics, that is, the rear recombination characteristics, are improved through the application of TiOₓ to the rear passivation layer 130. However, although TiOₓ has conductivity, the absolute electrical conductivity of TiOₓ is not excellent. In addition, since TiOₓ is an n-type material, it hinders the transfer of holes (+) moving from the light-absorbing layer 150 to the rear transparent electrode 120. That is, high electrical resistance exists at the interface between TiOₓ and CIGS. Therefore, although the rear recombination characteristics can be improved only by applying TiOₓ, there is a limit to improving the rear interfacial transport characteristics.

In consideration of the above-mentioned point, the conductive thin film pattern 140 is applied. That is, the conductive thin film pattern 140 is provided in some regions on the rear passivation layer 130 formed of TiOₓ, whereby ohmic contact between the light-absorbing layer 150 and the rear transparent electrode 120 may be induced via the conductive thin film pattern 140, thereby improving the rear interface transport characteristics.

In this case, even though the conductive thin film pattern 140 is not provided in the form of penetrating the rear passivation layer 130, but is provided on the rear passivation layer 130, ohmic contact between the light-absorbing layer 150 and the rear transparent electrode 120 is possible, because the rear passivation layer 130 is made of TiOₓ rather than Al₂O₃. When Al₂O₃ is applied as the passivation layer as in the crystalline silicon solar cell discussed above, the electrode is required to penetrate the passivation layer due to the non-conductive properties of Al₂O₃. However, since TiOₓ has conductivity unlike Al₂O₃, ohmic contact between the light-absorbing layer 150 and the rear transparent electrode 120 can be mediated by adjusting the thickness of TiOₓ. As another example, U.S. Patent Publication No. 2018-0138347 configures the passivation layer 106 with Al₂O₃, indicating that the electrical contact 108 penetrates the Al₂O₃ passivation layer 106 for the electrical connection between the light-absorbing layers 150 and 102 and the light reflection metal layer 104.

In addition, the electrical conductivity of TiOₓ can also be controlled through the contents of oxygen and impurity, thereby controlling the ohmic contact between the light-absorbing layer 150 and the rear transparent electrode 120. The electrical resistivity of TiOₓ must be controlled to be greater than 1 Ωcm, and to this end, the oxygen content in the process gas must be maintained at a certain ratio or more during sputtering-based deposition of TiOₓ. For example, it needs to be adjusted at 0.2 to 0.3%. Here, the impurities refer to any one of Nb, Sb, and S.

As described above, the rear recombination characteristics and the rear interfacial transport characteristics can be improved by combining the TiOₓ rear passivation layer 130 and the conductive thin film pattern 140, wherein the TiOₓ rear passivation layer 130 and the conductive thin film pattern 140 need to have an optimal structure. For example, when the area and volume of the conductive thin film pattern 140 provided in some regions on the rear passivation are too large, the rear interfacial transport characteristics are improved, while the rear recombination characteristics due to the rear passivation layer 130 are deteriorated. When the area of the conductive thin film pattern 140 is too small, the rear recombination characteristics are improved, but the effect of improving the rear interfacial transport characteristics by the conductive thin film pattern 140 is insignificant.

Considering these points, the conductive thin film pattern 140 is provided in a dot shape (see FIG. 2) or a linear shape (see FIG. 3), the distance between the conductive thin film patterns 140 should be set in consideration of the carrier diffusion length L_{D} of the light-absorbing layer 150, and the thickness of the conductive thin film pattern 140 should be designed in consideration of light transmittance.

Specifically, when the conductive thin film pattern 140 forms a dot shape, a plurality of conductive thin film patterns 140 are disposed to be spaced apart on the rear passivation layer 130, and the total area of the plurality of conductive thin film patterns 140 should not exceed 20% of the area of the rear passivation layer 130. If it exceeds 20%, the rear interfacial transport characteristics are improved, but the rear recombination characteristics by the rear passivation layer 130 are deteriorated.

In addition, preferably, the dot-shaped conductive thin film pattern 140 is designed to have a length or diameter of 0.1 to 2 μm and a thickness of 0.1 to 2 nm for sufficient light transmission. Furthermore, the distance between the conductive thin film patterns 140 should be equal to or less than 2 to 5 μm, which is comparable to the carrier diffusion length L_{D} of the light-absorbing layer 150.

When the conductive thin film pattern 140 is linear, the conductive thin film pattern 140 may be arranged in a lattice shape, and the distance between the conductive thin film patterns 140 is preferably designed to be equal to or less than 2 to 5 μm, which is comparable to the carrier diffusion length L_{D} of the light-absorbing layer 150. In addition, the linear conductive thin film pattern 140 is preferably designed to have a width of 0.1 to 2 μm and a thickness of 0.1 to 2 nm for sufficient light transmission. As an example, the conductive thin film pattern 140 may be formed of molybdenum (Mo).

Meanwhile, the rear transparent electrode 120 and the front transparent electrode 170 may be formed of any one of indium-based oxide, zinc-based oxide, and tin-based oxide. The indium-based oxide is any one of InOₓ, ITO, (W, Ce, Mo)-doped InOₓ, and IZO, the zinc-based oxide is (Al, Ga, B, Ti, F, H)-doped ZnOₓ, and the tin-based oxide is (F, Sb)-doped SnOₓ.

The buffer 160 layer may be formed of any one of CdS, InS(O,OH), ZnS(O, OH), ZnMgO, ZnTiO, ZnSnO, or a combination thereof.

Hereinbefore, the bifacial thin film solar cell according to an embodiment of the present invention has been described. Next, a method of manufacturing a bifacial thin film solar cell according to an embodiment of the present invention will be described.

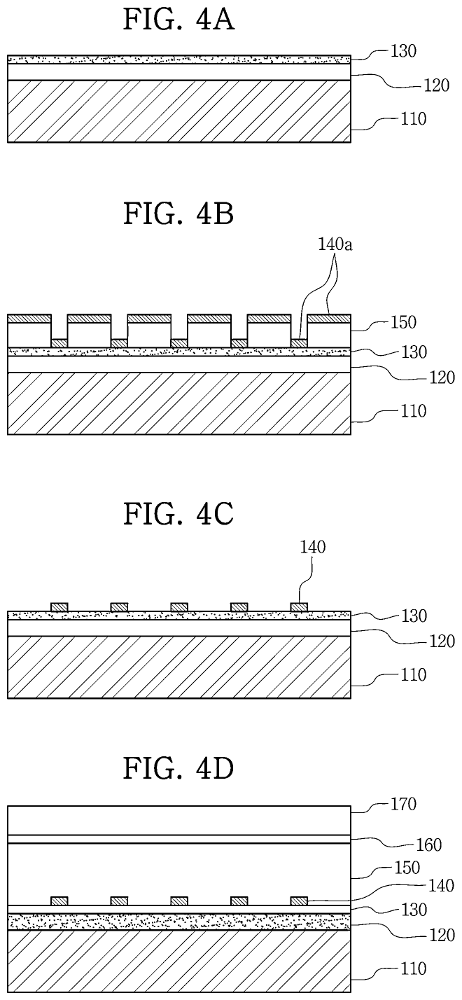

First, as shown in FIG. 4A, a rear transparent electrode 120 is stacked on a transparent substrate 110.

The transparent substrate 110 may be a glass substrate, and the rear transparent electrode 120 may be stacked using any one of sputtering, vacuum evaporation, and solution processes. Additionally, the rear transparent electrode 120 may be formed of any one of indium-based oxide, zinc-based oxide, and tin-based oxide. The indium-based oxide is any one of InOₓ, ITO, (W, Ce, Mo)-doped InOₓ, and IZO, the zinc-based oxide is (Al, Ga, B, Ti, F, H)-doped ZnOₓ, and the tin-based oxide is (F, Sb)-doped SnOₓ.

Subsequently, a rear passivation layer 130 is stacked on the rear transparent electrode 120. Like the rear transparent electrode 120, the rear passivation layer 130 may be stacked using any one of sputtering, vacuum evaporation, and solution processes.

The rear passivation layer 130 may be formed of TiOₓ or TaOₓ, which is an n-type metal oxide, or may be formed of TiOₓ or TaOₓ doped with any one element among Nb, Sb, and S. Most preferably, the rear passivation layer 130 may be formed of TiOₓ or Nb-doped TiOₓ (TNO). In order to control the conductivity, that is, the electrical resistivity of TiOₓ or Nb-doped TiOₓ (TNO), the oxygen content and/or impurity content of TiOₓ or Nb-doped TiOₓ(TNO) is adjusted, and preferably, the electrical resistivity of TiOₓ must be controlled to be greater than 1 Ωcm. To this end, the oxygen content in the process gas must be maintained at a certain ratio or more during sputter deposition of TiOₓ, and for example, it needs to be adjusted at 0.2 to 0.3%.

In a state in which the rear passivation layer 130 is stacked, a conductive thin film pattern 140 is formed on the rear passivation layer 130. Specifically, a mask exposing some regions of the rear passivation layer 130 is formed on the rear passivation layer 130 (see FIG. 4B). The mask may be formed by using a photolithography or an electron beam lithography process. Also, it may be formed by using a block copolymer mask material technology or a nanobead/sphere lithography process. Then, a conductive metal 140a, for example, Mo, which is a constituent material of the conductive thin film pattern 140, is deposited on the front surface of the rear passivation layer 130 including the mask. The conductive metal 140a may be deposited by using a sputtering or vacuum evaporation process. Then, when the mask is removed, the conductive thin film pattern 140 existing only in some regions of the rear passivation layer 130 is formed (see FIG. 4C).

In the above process, when patterning the mask that exposes some regions of the rear passivation layer 130, the region exposed by the mask may form a dot shape or a linear shape. In addition, the distance between the dots or the distance between the lines should be equal to or less than 2 to 5 μm, which is comparable to the carrier diffusion length L_{D} of the light-absorbing layer 150, and it is desirable to pattern the mask so that the length of dot or the width of linear shape is 0.1 to 2 μm. Furthermore, the total area of the region exposed by the mask should not exceed 20% of the area of the rear passivation. The region exposed by the mask corresponds to a region in which the conductive thin film pattern 140 is formed, and when the total area of the conductive thin film pattern 140 exceeds 20% of the area of the rear passivation, the rear passivation characteristic by the rear passivation layer 130 is deteriorated. In addition, when the conductive metal 140a is deposited in the above process, the conductive metal 140a is preferably deposited to have a thickness of 0.1 to 2 nm to secure sufficient light transmittance.

In a state in which the conductive thin film pattern 140 is formed on the rear passivation layer 130, a material of the light-absorbing layer 150, that is, CIGS is stacked on the front surface of the rear passivation layer 130 including the conductive thin film pattern 140, and then heat treatment is performed to form the light-absorbing layer 150 (see FIG. 4D). When the light-absorbing layer 150 is completely formed, the conductive thin film pattern 140 is formed to be included within the light-absorbing layer 150.

Subsequently, when the buffer layer 160 and the front transparent electrode 170 are sequentially stacked on the light-absorbing layer 150, the method of manufacturing a bifacial thin film solar cell according to an embodiment of the present invention is completed. The buffer layer 160 may be formed of any one of CdS, InS(O,OH), ZnS(O, OH), ZnMgO, ZnTiO, ZnSnO, or a combination thereof, and the front transparent electrode 170 may be formed of the same material as the rear transparent electrode 120.

Meanwhile, the bifacial thin film solar cell of the present invention may be implemented in the form of a single integrated module. That is, it may be manufactured in a form in which a plurality of solar cells is provided on one substrate. In this case, scribing P1 for cell-to-cell insulation of the rear transparent electrode 120, scribing P2 for cell-to-cell connection between the rear transparent electrode 120 and the front transparent electrode 170, and scribing P3 for cell-to-cell insulation of the front transparent electrode 170 are required.

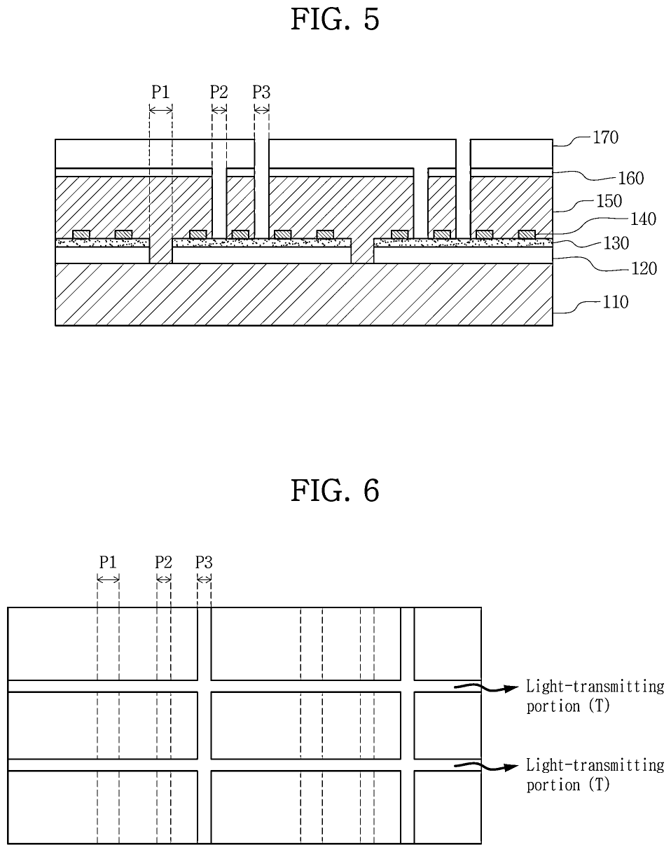

This will be described in detail as follows (see FIG. 5).

In a state where the rear transparent electrode 120 and the rear passivation layer 130 are sequentially stacked on the transparent substrate 110, and the conductive thin film pattern 140 is formed on the rear passivation layer 130, the rear transparent electrode 120 and the rear passivation layer 130 are scribed in a certain area along a scribing line to divide them into a plurality of cells and to insulate the rear transparent electrode 120 between neighboring cells. In this case, the scribing line is referred to as a P1 region, the rear transparent electrode 120 is divided into a plurality of cells by the P1 region, and the rear transparent electrode 120 between neighboring cells is electrically insulated by the P1 region. The scribing process for the P1 region and the scribing processes for the P2 region and the P3 region, which will be described later, may be performed using a laser.

Subsequently, the light-absorbing layer 150 and the buffer layer 160 are sequentially stacked on the front surface of the substrate including the conductive thin film pattern 140. Accordingly, the light-absorbing layer 150 is also filled in the P1 region. Then, the buffer layer 160 and the light-absorbing layer 150 are scribed along the P2 region to expose the rear passivation layer 130.

In this state, the front transparent electrode 170 is stacked on the front surface of the buffer layer 160. In this case, the front transparent electrode 170 is also filled in the P2 region. As the front transparent electrode 170 is filled in the P2 region, the front transparent electrode 170 is electrically connected to the conductive thin film pattern 140 on the rear passivation layer 130. Here, the front transparent electrode 170 and the conductive thin film pattern 140 on the rear passivation layer 130 are provided in adjacent cells, respectively.

In a state in which the front transparent electrode 170 is stacked, the front transparent electrode 170, the buffer layer 160, and the light-absorbing layer 150 are scribed along the P3 region to insulate the front transparent electrode 170 between adjacent cells.

Through the above process, a structure in which a plurality of bifacial thin film solar cells is integrated on one transparent substrate 110 may be completed.

In addition to the integration of the above-described bifacial thin film solar cell, light-transmitting properties may be additionally provided. In a state in which the integration process is completed, as shown in FIG. 6, the front transparent electrode 170, the buffer layer 160, the light-absorbing layer 150, and the rear transparent electrode 120 are removed along the light-transmitting portion region (T) to expose the transparent substrate 110. A portion where the front transparent electrode 170, the buffer layer 160, the light-absorbing layer 150, and the rear transparent electrode 120 are selectively removed corresponds to the light-transmitting portion region (T). The area of the light-transmitting portion region (T) may be selectively adjusted, thereby controlling the light transmittance of the bifacial thin film solar cell. Here, the rear transparent electrode 120 may not be removed, and in this case, the light-transmitting portion region (T) has a structure in which the rear transparent electrode 120 is exposed to the outside.

Hereinabove, the bifacial thin film solar cell and the manufacturing method thereof according to an embodiment of the present invention have been described. Hereinafter, the present invention will be described in more detail through experimental examples.

### Experimental Example 1: Rear Passivation Characteristics Depending on Whether TiOₓ is Applied or not

Indium tin oxide (ITO) was deposited to a thickness of 600 nm on a soda lime glass substrate by a sputtering process, and then a TiO₂ thin film was deposited. The TiO₂ thin films were deposited by varying their thickness (t) to 0, 1, 2, and 4 nm. A CIGS thin film was deposited on the TiO₂ thin film at a substrate temperature of 450° C. by a 3-stage co-evaporation process. Subsequently, a CdS thin film was deposited by chemical bath deposition, i-ZnO and indium zinc oxide (IZO) thin films were deposited by sputtering, and then an Ag metal electrode pattern was deposited to complete a CIGS thin film solar cell.

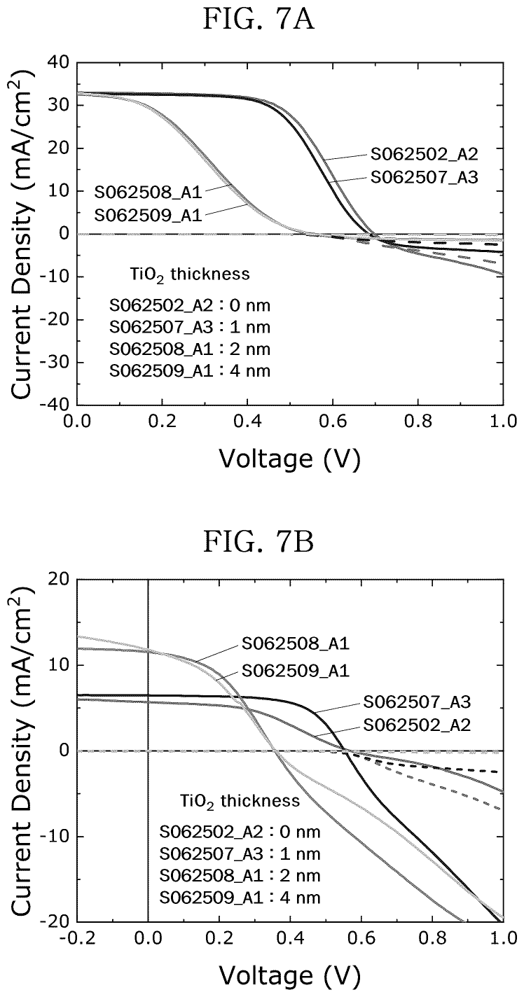

For the completed CIGS thin film solar cell, light having an intensity of 1-sun is irradiated on the front and rear surfaces, respectively, and current-voltage characteristics are measured. FIG. 7A shows current-voltage characteristic results of the fabricated samples according to front light incidence, FIG. 7B shows the results of current density-voltage (jV) characteristics according to rear light incidence, and Table 1 below summarizes the results of FIGS. 7A and 7B.

TABLE 1
<Front and rear photocurrent characteristics of bifacial CIGS solar
cells depending on whether TiO₂ is applied or not, and thickness>

| | | |
|---|---|---|
| TiO₂ | Photocurrent | Rear |
| thickness | characteristics | photocurrent |

| (nm) | Front | Rear | ratio |
|---|---|---|---|
| 0 | 32.97 | 5.67 | 0.172 |
| 1 | 32.68 | 6.46 | 0.198 |
| 2 | 32.51 | 11.52 | 0.354 |
| 4 | 32.73 | 11.80 | 0.361 |

Referring to FIGS. 7A, 7B, and Table 1, the thin film solar cell to which TiO₂ is not applied (TiO₂ 0 nm) is in a high resistance state, which is judged to be due to the high resistance of the ITO/CIGS interface. In addition, the photocurrent was significantly reduced under the rear light incident condition (photocurrent ratio of 0.172), which is due to high charge recombination caused by defects at the ITO/CIGS interface. This result means that the passivation characteristics of the ITO/CIGS interface are poor. Even in the case of a thin film solar cell to which the TiO₂ thin film is applied at 1 nm, there is no significant difference in the jV characteristics, and the improvement in the rear photocurrent (to photocurrent ratio of 0.198) is also insignificant.

On the other hand, in the case of a thin film solar cell with a TiO₂ thin film applied at 2 nm and 4 nm, it can be seen that the fill factor (FF) is significantly reduced under the front light incident condition because the interfacial resistance is very high, but the photocurrent is greatly increased under the rear light incident condition (photocurrent ratio of 0.354-0.361), thereby improving the ITO/CIGS interface passivation characteristics.

### Experimental Example 2: Rear Passivation and Interfacial Resistance Characteristics According to the Application of Mo Ultra-Thin Film Layer

In order to resolve the high resistance of the ITO/CIGS interface, a Mo ultra-thin layer of 0.5 nm thickness was applied to the thin film solar cell of Experimental Example 1. The Mo layer (0.5 nm thick) has a light absorption rate of 2% or less, can transmit most of the light, and can be expected to improve interfacial resistance characteristics.

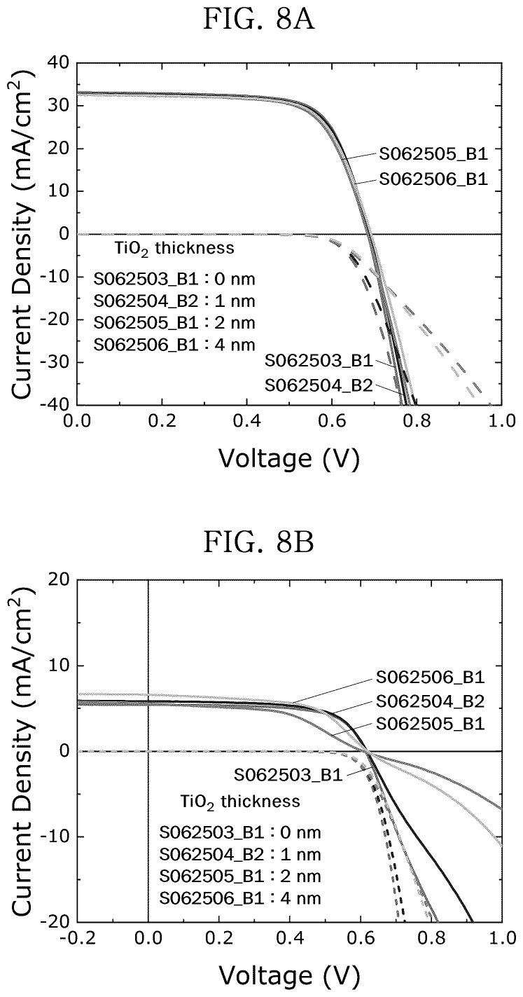

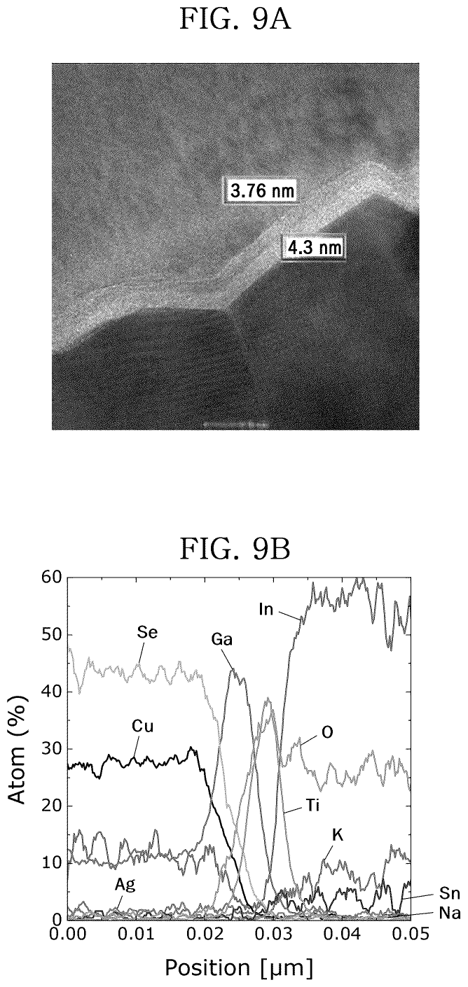

According to the jV results measured under the front light incident condition (see FIG. 8A), it is shown that Mo layer (0.5 nm thick) can significantly lower the interfacial resistance regardless of the TiO₂ thickness. However, as the TiO₂ thickness is increased from 0 to 4 nm, the series resistance is slightly increased.

On the other hand, the jV results measured under the rear light incident conditions (see FIG. 8B) show that the interfacial passivation capability previously confirmed at the TiO₂ thickness of 2 nm or more in Experimental Example 1 disappeared in the cell structure to which Mo (0.5 nm) was added.

These results can be said to show that the introduction of Mo in some regions can be expected to achieve both the effect of improving the rear passivation characteristics by TiO₂ and the interfacial transport characteristics by Mo.

### Experimental Example 3: Ga Precipitation Characteristics

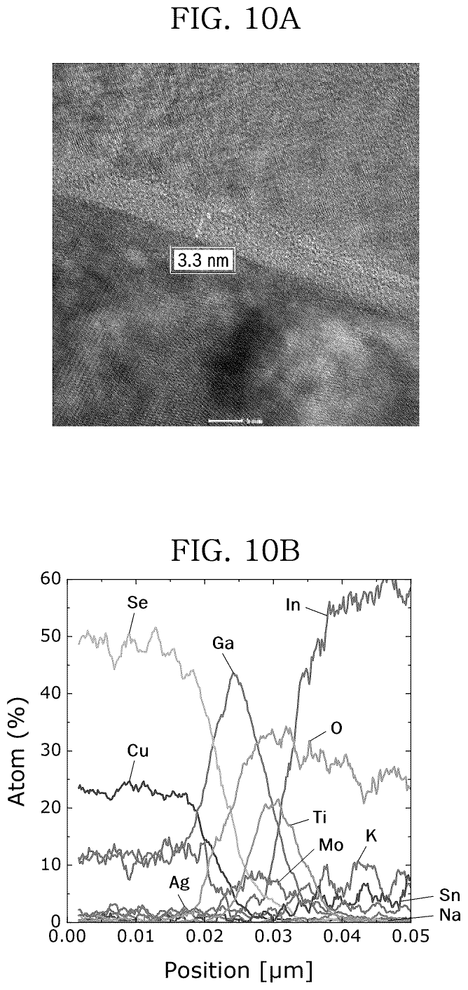

TEM and EDS analysis were performed on ITO/TiO₂(4 nm)/CIGS and ITO/TiO₂(4 nm)/Mo(0.5 nm)/CIGS respectively manufactured in Experimental Example 1 and Experimental Example 2. FIGS. 9A and 9B are TEM-EDS analysis results of ITO/TiO₂(4 nm)/CIGS manufactured in Experimental Example 1, and FIGS. 10A and 10B are TEM-EDS analysis results of ITO/TiO₂(4 nm)/Mo(0.5 nm)/CIGS manufactured in Experimental Example 2.

Referring to FIGS. 9A, 9B, 10A, and 10B, the oxygen of ITO reacts with the Ga of CIGS between the ITO layer and the CIGS layer to form GaOₓ. Although the TiO₂ structure remains stable, it does not appear to be effective in suppressing GaOₓ formation. It seems that the presence of TiO₂ has a limitation in blocking oxygen diffusion. However, even when the Mo ultra-thin film layer is applied, GaOₓ formation cannot be suppressed, and it is believed that the oxygen passing through the TiOₓ/Mo layer reacts to form the GaOₓ layer. As a result, each interface structure is formed of ITO/TiO₂/GaOₓ/CIGS and ITO/TiO₂/Mo/GaOₓ/CIGS. From the experimental fact that although both interfaces contain GaOₓ/CIGS regions, charge transfer in the second interface structure is facilitated, while rear passivation performance is deteriorated, it is believed that the GaOₓ/CIGS interface does not have any special function in terms of charge transport or passivation performance. Therefore, it can be said that the TiO₂/GaOₓ interface determines the interfacial charge transport and passivation performance. The application of Mo creates additional surface defects at the interface, promoting recombination between p-type CIGS and n-type TiO₂, thereby facilitating charge transfer, but reducing passivation performance.

### Experimental Example 4: Passivation and Photocurrent Characteristics According to Oxygen Content of TiOₓ

The passivation characteristics and electrical characteristics according to the oxygen content of TiOₓ were examined.

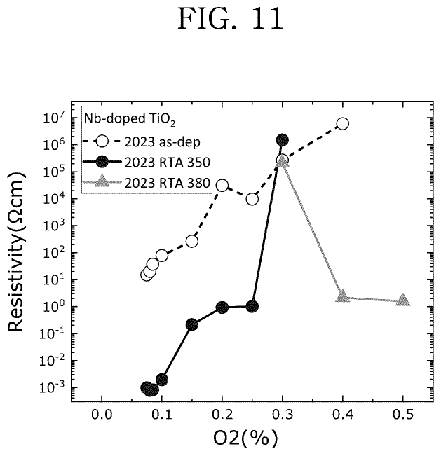

In manufacturing an ITO/TiOₓ/CIGS structure according to Experimental Example 1, an Nb-doped TiOₓ (Nb content: 10 wt %) sputter target was sputtered to deposit TNO (titanium niobium oxide), and the flow rate of oxygen gas in the sputtering gas was adjusted to have an oxygen content (O₂/(Ar+O₂)) of 0.08 to 0.5%. Subsequently, the deposited TNO was subjected to rapid heat treatment (RTA) at 350° C. and 380° C. (proceeded for 30 minutes in an atmosphere of 0.5% H₂ and a vacuum degree of 1 to 10 Torr). FIG. 11 is a result showing electrical resistivity characteristics according to oxygen content of TNO (As-dep) not subjected to rapid heat treatment and TNO (RTA 350 and RTA 380) subjected to rapid heat treatment.

Referring to FIG. 11, in a state in which the rapid heat treatment is not performed (As-dep), the electrical resistivity is generally very high and tends to increase significantly with the increase of the oxygen content. After the rapid heat treatment, crystallization occurs and thus the magnitude of the electrical resistivity decreases by orders of 2 to 4, and when the oxygen content is 0.1% or less, it decreases to 10⁻³ Ωcm, but at higher oxygen content, a high electrical resistivity value of 10⁻¹ to 1 Ωcm is maintained. When the oxygen content is 0.3% or higher, crystallization does not occur even with rapid heat treatment, resulting in a resistivity as high as that of a nonconductor. However, when the temperature is increased (380 degrees), crystallization occurs again and thus the resistivity is reduced.

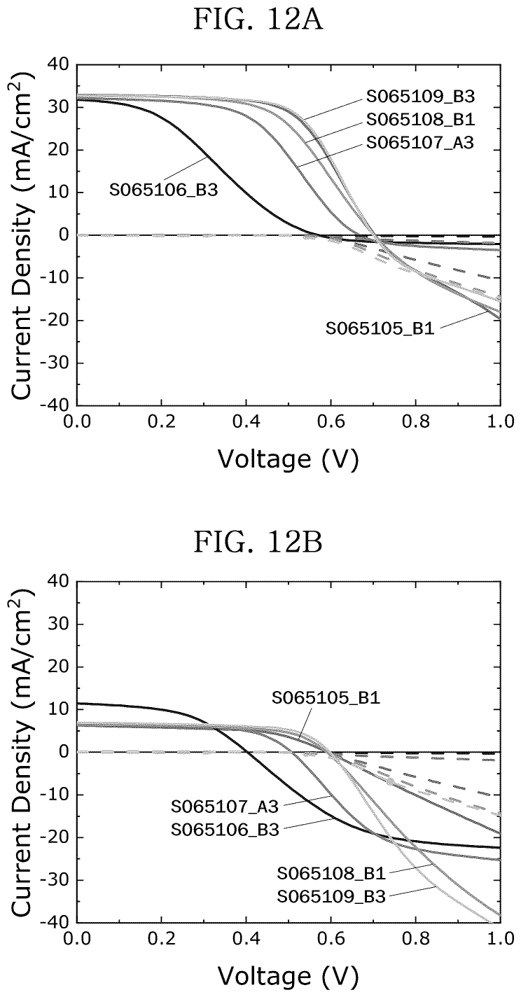

Front and rear photocurrent characteristics were examined for thin film solar cells to which TNO having an oxygen content of 0.08% and 0.2% was applied. FIGS. 12A and 12B are experimental results showing front photocurrent characteristics and rear photocurrent characteristics, respectively, and Table 2 below summarizes these results.

TABLE 2
<Front and rear photocurrent characteristics
of thin film solar cells with TNO applied>

| | | | Eff | Voc | FF | Jsc [mA/cm²] | | |
|---|---|---|---|---|---|---|---|---|
| Sample | TNO | O₂ | [%] | [V] | [%] | Front | Rear | Ratio |
| Ref. S065105_B1 | 0 | | 14.5 | 0.705 | 62.3 | 33.0 | 6.3 | 0.19 |
| S065106_B3 | 4 nm | 0.2% | 6.0 | 0.570 | 33.2 | 31.8 | 11.4 | 0.36 |
| S065107_A3 | 4 nm | 0.08% | 11.2 | 0.688 | 52.3 | 32.1 | 6.8 | 0.21 |
| S065108_B1 | 4 nm/RTA | 0.08% | 13.2 | 0.702 | 57.3 | 32.9 | 6.5 | 0.20 |
| S065109_B3 | 1.5 nm/RTA | 0.08% | 14.8 | 0.701 | 64.6 | 32.7 | 7.0 | 0.21 |

Referring to FIGS. 12A, 12B and Table 2, the higher the electrical resistivity of TNO, the greater the interfacial barrier that interferes with the charge transfer, so that FF of the solar cell is rapidly reduced. Only TNO (O₂ 0.2%, no heat treatment, thickness 4 nm) with the highest resistivity of 1×10⁴ Ωcm has excellent rear passivation ability during rear light incident.

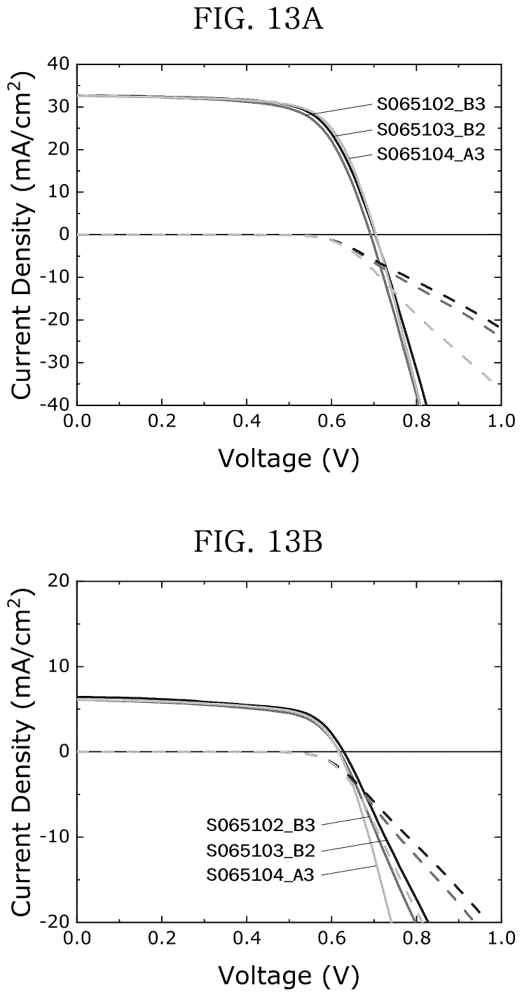

Subsequently, after the Mo thin film layer (0.5 nm) was additionally applied to the thin film solar cell to which TNO having an oxygen content of 0.08% and 0.2% was applied, front and rear photocurrent characteristics were examined. FIGS. 13A and 13B are experimental results showing front photocurrent characteristics and rear photocurrent characteristics, respectively, and Table 3 below summarizes these results.

Referring to FIGS. 13A, 13B, and Table 3, regardless of the resistance of TNO, the addition of the Mo thin film layer greatly improved the charge interfacial transport performance, so that similar or better FF could be provided compared to the case without TNO. In addition, when the electrical resistivity is increased, TNO also exhibits interfacial passivation ability, but when the electrical resistivity is lowered, the passivation ability is lost. Therefore, when the Mo thin film layer is applied, the interfacial passivation ability is significantly reduced, but the charge transfer ability is excellent, so TNO can be applied to the rear passivation structure incorporating the Mo pattern such as the structure in this patent application.

TABLE 3
<Front and rear photocurrent characteristics of thin film
solar cells with TNO and Mo thin film layers applied>

| | | | | | Jsc | |
|---|---|---|---|---|---|---|
| | | | Efficiency | Voc | [mA/cm²] | FF |
| Sample | TNO | O₂ | [%] | [V] | J-V | [%] |
| Ref. | — | — | 15.2 | 0.692 | 32.7 | 67.0 |
| S065102_B3 | | | | | | |
| S065103_B2 | 4 nm | 0.2% | 15.7 | 0.704 | 32.7 | 68.3 |
| S065104_A3 | 4 nm | 0.08% | 16.0 | 0.705 | 32.6 | 69.6 |

What is claimed is:

1. A bifacial thin film solar cell including:
a rear transparent electrode stacked on a transparent substrate;
a rear passivation layer stacked on the rear transparent electrode;
a conductive thin film pattern formed in some regions on the rear passivation layer;
a light-absorbing layer stacked on the front surface of the rear passivation layer including the conductive thin film pattern;
a buffer layer stacked on the light-absorbing layer; and
a front transparent electrode stacked on the buffer layer.

2. The bifacial thin film solar cell according to claim 1, wherein the rear passivation layer is formed of TiOₓ or TaOₓ.

3. The bifacial thin film solar cell according to claim 2, wherein the electrical resistivity of TiOₓ is greater than 1 Ωcm.

4. The bifacial thin film solar cell according to claim 1, wherein the rear passivation layer is formed of TiOₓ or TaOₓ doped with any one element among Nb, Sb, and S.

5. The bifacial thin film solar cell according to claim 4, wherein the electrical resistivity of TiOₓ doped with any one of Nb, Sb, and S is greater than 1 Ωcm.

6. The bifacial thin film solar cell according to claim 1, wherein the conductive thin film pattern has a dot shape or a linear shape, and a plurality of conductive thin film patterns are arranged on the rear passivation layer to be spaced apart from each other.

7. The bifacial thin film solar cell according to claim 6, the total area of the plurality of conductive thin film patterns does not exceed 20% of the area of the rear passivation layer.

8. The bifacial thin film solar cell according to claim 6, when the conductive thin film pattern has a dot shape,
the conductive thin film pattern has a length or diameter of 0.1 to 2 μm, a thickness of 0.1 to 2 nm, and
a distance between the conductive thin film patterns which is equal to or less than a carrier diffusion length (L_{D}) in the light-absorbing layer.

9. The bifacial thin film solar cell according to claim 6, when the conductive thin film pattern has a linear shape,
the linear conductive thin film pattern has a width of 0.1 to 2 μm, a thickness of 0.1 to 2 nm, and
a distance between the conductive thin film patterns which is equal to or less than a carrier diffusion length (L_{D}) in the light-absorbing layer.

10. The bifacial thin film solar cell according to claim 1, wherein the conductive thin film pattern is formed of molybdenum (Mo).

11. The bifacial thin film solar cell according to claim 1, wherein the stacked thickness of the rear passivation layer is 2 to 4 nm.

12. The bifacial thin film solar cell according to claim 1, wherein the light-absorbing layer is formed of CIGS (Cu(In₁₋ₓ, Gaₓ)(Se,S)₂).

13. The bifacial thin film solar cell according to claim 1, wherein the rear transparent electrode and the front transparent electrode is formed of any one of indium-based oxide, zinc-based oxide, and tin-based oxide,
wherein the indium-based oxide is any one of InOₓ, ITO, (W, Ce, Mo)-doped InOₓ, and IZO, the zinc-based oxide is (Al, Ga, B, Ti, F, H)-doped ZnOₓ, and the tin-based oxide is (F, Sb)-doped SnOₓ.

14. The bifacial thin film solar cell according to claim 1, wherein the buffer layer is provided between the light-absorbing layer and the front transparent electrode, and
the buffer layer is formed of any one of CdS, InS(O,OH), ZnS(O, OH), ZnMgO, ZnTiO, ZnSnO, or a combination thereof.

15. The bifacial thin film solar cell according to claim 1, wherein the front transparent electrode, light-absorbing layer, and rear passivation layer in a specific region are removed to provide a light-transmitting portion region in which the rear transparent electrode is exposed.

16. The bifacial thin film solar cell according to claim 15, wherein the light transmittance of the bifacial thin film solar cell can be controlled by adjusting the area of the light-transmitting portion region.

17. The bifacial thin film solar cell according to claim 1, wherein a P1 region is provided in which the rear passivation layer and the rear transparent electrode are removed in a certain area, a P2 region is provided in which the buffer layer and the light-absorbing layer are removed in a certain area, and a P3 region is provided in which the front transparent electrode, the buffer layer, and the light-absorbing layer are removed in a certain area,
wherein the rear transparent electrodes of neighboring cells are insulated by the P1 region, the rear transparent electrode and the front transparent electrode of neighboring cells are connected by the P2 region, and the front transparent electrodes of neighboring cells are insulated by the P3 region.

18. A method of manufacturing a bifacial thin film solar cell including the steps of:
forming a rear transparent electrode on a transparent substrate;
sequentially stacking a rear passivation layer on the rear transparent electrode;
forming a conductive thin film pattern on the rear passivation layer;
forming a light-absorbing layer on the front surface of the rear passivation layer including the conductive thin film pattern; and
forming a front transparent electrode on the light-absorbing layer.

19. The method of manufacturing a bifacial thin film solar cell according to claim 18,
wherein the step of forming a conductive thin film pattern on the rear passivation layer includes the substeps of: forming a mask that exposes some regions of the rear passivation layer on the rear passivation layer,
depositing a conductive metal on the front surface of the rear passivation layer including the mask, and
removing the mask to form a conductive thin film pattern in some regions of the rear passivation layer.

20. The method of manufacturing a bifacial thin film solar cell according to claim 18, wherein the rear passivation layer is formed of TiOₓ or TaOₓ, or is formed of TiOₓ or TaOₓ doped with any one element among Nb, Sb, and S.

21. The method of manufacturing a bifacial thin film solar cell according to claim 18, further including a step of removing the front transparent electrode, the light-absorbing layer, and the rear passivation layer in a specific region to form a light-transmitting portion region in which the rear transparent electrode is exposed.

22. The method of manufacturing a bifacial thin film solar cell according to claim 18, further including a step of: before forming the light-absorbing layer,
scribing the rear transparent electrode and the rear passivation layer in a certain area along the P1 region to divide them into a plurality of cells and insulating the rear transparent electrode between neighboring cells in a state in which the conductive thin film pattern is formed on the rear passivation layer.

23. The method of manufacturing a bifacial thin film solar cell according to claim 18, further including a step of: after forming the light-absorbing layer,
exposing the rear passivation layer by scribing the light-absorbing layer along the P2 region.

24. The method of manufacturing a bifacial thin film solar cell according to claim 22, further including a step of: in a state in which the front transparent electrode is stacked,
insulating the front transparent electrode between neighboring cells by scribing the front transparent electrode and the light-absorbing layer along the P3 region.
